(19) United States
(12) Patent Application Publication
(10) Pub. No.: US 2011/0139233 A1
(43) Pub. Date: Jun. 16, 2011

(54) QUANTUM DOT SOLAR CELL

(75) Inventors: Zhi Zheng, Shanghai (CN); Linan Zhao, Shanghai (CN); Marilyn Wang, Shanghai (CN); Xuanbin Liu, Shanghai (CN)

(73) Assignee: Honeywell International Inc., Morristown, NJ (US)

(21) Appl. No.: 12/636,402

(22) Filed: Dec. 11, 2009

(51) Int. Cl. H01L 31/0352; H01L 31/18

(52) U.S. Cl. 136/256; 438/57; 257/E31.033

(57) ABSTRACT

Quantum dot solar cells with enhanced efficiency are disclosed. An example solar cell includes an electron conductor layer, a quantum dot layer and a hole conductor layer. The electron conductor layer may include a plurality of nanoparticles having an average outer dimension that is greater than about 25 nanometers. The hole conductor layer may include an electrolytic salt, and/or a low surface tension solvent, as desired.

### TECHNICAL FIELD

The disclosure relates generally to solar cells, and more particularly to quantum dot solar cells.

### BACKGROUND

A wide variety of solar cells have been developed for converting sunlight into electricity. Of the known solar cells, each has certain advantages and disadvantages. There is an ongoing need to provide alternative solar cells as well as alternative methods for manufacturing solar cells.

### SUMMARY

The disclosure relates generally to solar cells. In some instances, a solar cell may include quantum dots as light sensitizers. An example solar cell may include an electron conductor layer, a quantum dot layer, and a hole conductor layer. The quantum dot layer may be coupled to the electron conductor layer, and the hole conductor layer may be coupled to the quantum dot layer. The hole conductor layer may include sulfur and a low surface tension solvent. Such an electron conductor layer may increase the efficiency of the solar cell.

Another example solar cell may likewise include an electron conductor layer, a quantum dot layer, and a hole conductor layer, where the quantum dot layer is coupled to the electron conductor layer, and the hole conductor layer is coupled to the quantum dot layer. In this example, the hole conductor layer may include an electrolytic salt and/or a low surface tension solvent. Such a hole conductor layer may increase the efficiency of the solar cell.

In some instances, a solar cell may include an electron conductor layer that includes a plurality of nanoparticles having an average outer dimension (e.g. diameter) that is greater than about 25 nanometers, and a hole conductor layer that includes an electrolytic salt and/or a low surface tension solvent.

The above summary is not intended to describe each and every disclosed embodiment or every implementation of the disclosure. The Description which follows more particularly exemplifies various examples.

### BRIEF DESCRIPTION OF THE FIGURE

The following description should be read with reference to the drawing. The drawing, which is not necessarily to scale, depicts a selected embodiment and is not intended to limit the scope of the disclosure. The disclosure may be more completely understood in consideration of the following description of various embodiments in connection with the accompanying drawing, in which:

FIG. 1 is a schematic cross-sectional side view of an illustrative but non-limiting example of a solar cell.

While the disclosure is amenable to various modifications and alternative forms, specifics thereof have been shown by way of example in the drawing and will be described in detail. It should be understood, however, that the intention is not to limit the invention to the particular embodiments or examples described. On the contrary, the intention is to cover all modifications, equivalents, and alternatives falling within the spirit and scope of the disclosure.

### DESCRIPTION

For the following defined terms, these definitions shall be applied, unless a different definition is given in the claims or elsewhere in this specification.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

A wide variety of solar cells (which also may be known as photovoltaics and/or photovoltaic cells) have been developed for converting sunlight into electricity. Some solar cells include a layer of crystalline silicon. Second and third generation solar cells often use a film of photovoltaic material (e.g., a “thin” film) deposited or otherwise provided on a substrate. These solar cells may be categorized according to the photovoltaic material used. For example, inorganic thin-film photovoltaics may include a thin film of amorphous silicon, microcrystalline silicon, CdS, CdTe, Cu₂S, copper indium diselenide (CIS), copper indium gallium diselenide (CIGS), etc. Organic thin-film photovoltaics may include a thin film of a polymer or polymers, bulk heterojunctions, ordered heterojunctions, a fullerence, a polymer/fullerence blend, photosynthetic materials, etc. These are only examples.

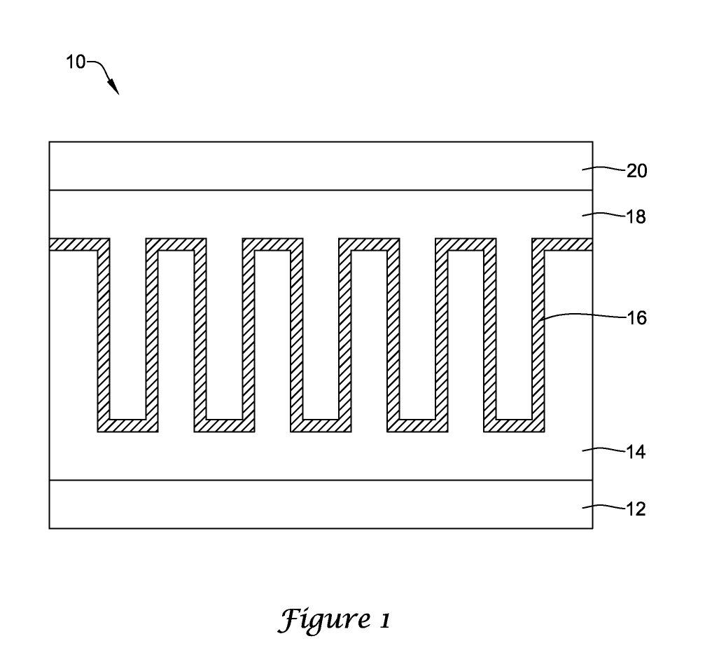

FIG. 1 is a schematic cross-sectional side view of an illustrative solar cell 10. In the illustrative embodiment, solar cell 10 includes a substrate or first electrode (e.g., an anode or negative electrode) 12. An electron conductor layer 14 may be electrically coupled to or otherwise disposed on electrode 12. Electron conductor layer 14 may include or be formed so as to take the form of a structured pattern or array, such as a structured nano-materials or other structured pattern or array, as desired. The structured nanomaterials may include clusters or arrays of nanospheres, nanotubes, nanorods, nanowires, nano-inverse opals or any other suitable nanomaterials as desired. A quantum dot layer 16 is shown electrically coupled to or otherwise disposed on electron conductor layer 14. In at least some embodiments, quantum dot layer 16 may be disposed over and “fill in” the structured pattern or array of electron conductor layer 14. A hole conductor 18 may be electrically coupled to or otherwise disposed on quantum dot layer 16. Solar cell 10 may also include a second electrode 20 (e.g., an cathode or positive electrode) that is electrically coupled to hole conductor layer 18.

Substrate/electrode 12 may be made from a number of different materials including polymers, glass, and/or transparent materials. For example, substrate 12 may include polyethylene terephthalate, polyimide, low-iron glass, fluorine-doped tin oxide, indium tin oxide, Al-doped zinc oxide, any other suitable conductive inorganic element(s) or compound(s), conductive polymer(s), and other electrically conductive materials, combinations thereof, or any other suitable materials.

Electron conductor layer 14 may be formed of any suitable material or material combination. In some cases, electron conductor layer 14 may be an n-type electron conductor. The electron conductor layer 14 may be metallic, such as TiO₂ or ZnO. In some cases, electron conductor layer 14 may be an electrically conducting polymer, such as a polymer that has been doped to be electrically conducting or to improve its electrical conductivity.

As indicated above, in at least some embodiments, electron conductor layer 14 may be formed or otherwise include a structured pattern or array of, for example, nanoparticles. In at least some embodiments, electron conductor layer 14 may include a plurality of nanoparticles such as nanospheres or the like with relatively large average outer particle dimensions (e.g. diameters). In one illustrative embodiment, the electron conductor layer 14 of solar cell 10 may include TiO₂ particles with an average particle outer diameter of about 25-100 nanometers, 25-45 nanometers, about 30-40 nanometers, or about 37 nanometers. When so configured, electron conductor layer 14 may allow for easier infiltration of quantum dot layer 16 onto electron conductor layer 14, and/or may a reduced interfacial area with hole conductor layer 18, which may reduce electron-hole recombination and improve the energy conversion efficiency of solar cell 10.

In some embodiments, quantum dot layer 16 may include one quantum dot or a plurality of quantum dots. Quantum dots are typically very small semiconductors, having dimensions in the nanometer range. Because of their small size, quantum dots may exhibit quantum behavior that is distinct from what would otherwise be expected from a larger sample of the material. In some cases, quantum dots may be considered as being crystals composed of materials from Groups II-VI, III-V, or IV-VI materials. The quantum dots employed herein may be formed using any appropriate technique. Examples of specific pairs of materials for forming quantum dots include, but are not limited to, MgO, MgS, MgSe, MgTe, CaO, CaS, CaSe, CaTe, SrO, SrS, SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs and InSb.

In some embodiments, solar cell 10 may include a bifunctional ligand layer (not shown) that may help to couple quantum dot layer 16 with electron conductor layer 14. At least some of the bifunctional ligands within the bifunctional ligand layer may be considered as including electron conductor anchors that may bond to electron conductor layer 14, and quantum dot anchors that may bond to individual quantum dots within quantum dot layer 16. A wide variety of bifunctional ligand layers are contemplated for use with the solar cells disclosed herein.

Hole conductor layer 18 may be considered as being coupled to quantum dot layer 16. In some cases, two layers may be considered as being coupled if one or more molecules or other moieties within one layer are bonded or otherwise secured to one or more molecules within another layer. In some instances, coupling infers the potential passage of electrons from one layer to the next.

Hole conductor layer 18 may be formed of any suitable material or material combination. For example, hole conductor layer 18 may be a p-type electron conductor. In some cases, hole conductor layer 18 may include a conductive polymer, but this is not required. In some cases, the conductive polymer may include a monomer that has an alkyl chain that terminates in a second quantum dot anchor. The conductive polymer may, for example, be or otherwise include a polythiophene that is functionalized with a moiety that bonds to quantum dots. In some cases, the polythiophene may be functionalized with a thio or thioether moiety.

An illustrative but non-limiting example of a suitable conductive polymer has

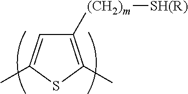

as a repeating unit, where R is absent or alkyl and m is an integer ranging from about 6 to about 12.

Another illustrative but non-limiting example of a suitable conductive polymer has

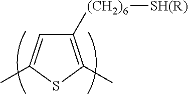

as a repeating unit, where R is absent or alkyl.

Another illustrative but non-limiting example of a suitable conductive polymer has

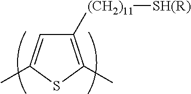

as a repeating unit, where R is absent or alkyl.

Another illustrative but non-limiting example of a suitable conductive polymer has

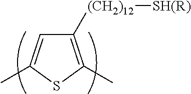

as a repeating unit, where R is absent or alkyl.

In some instances, hole conductor layer 18 may include sulfur-based materials or electrolytes, sulfur-based electrolytic gels, ionic liquids, spiro-OMeTAD (2,20,7,70-tetrakis-(N,N-di-p-methoxyphenylamine)9,90-spirobifluorene), poly-3-hexylthiophen (P3HT), and/or the like. It is contemplated that forming such a hole conductor layer 18 may include providing a material (e.g., a sulfur-based material in liquid form) for forming hole conductor layer 18. A mixture of, for example, de-ionized water and a low surface tension solvent (e.g., methanol) may be used as a solvent for the hole conductor layer 18 material. In one specific example, the hole conductor layer 18 may include a sulfur-based liquid hole conductor material mixed in a low surface tension solvent, where the low surface tension solvent is a mixture that includes water and methanol. The low surface tension solvent may have a better affinity with the electron conductor layer 14 (e.g., TiO₂), which may help inhibit adsorption of H₂O on the TiO₂ surface, and may reduce electron-hole recombination and improve the overall efficiency of solar cell 10.

In at least some embodiments, the hole conductor layer 18 may be enhanced, by the addition of an electrolytic salt. For example, an electrolytic salt (e.g., KCl, NaF, etc.) may be added to the hole conductor layer material as an additive during manufacture. It is believed that the addition of such an electrolytic salt may reduce the internal electrical resistance of the hole conductor layer 18, and may thus improve the overall efficiency of solar cell 10.

In some instances, a solar cell may be assembled by growing nanoparticles of n-type semiconducting titanium dioxide (TiO₂) on a glass substrate, optionally followed by a sintering process. Next, quantum dots and a hole conductor layer may be synthesized. In some cases, the solar cell may be assembled by combining the individual components in a one-pot synthesis, but this is not required. In one example, a method of manufacturing a solar cell 10 may include providing electron conductor layer 14, coupling quantum dot layer 16 to electron conductor layer 14, and coupling hole conductor layer 18 to quantum dot layer 16. As disclosed above, the electron conductor layer 14 may include TiO₂ or other particles with an average particle outer dimension (e.g. diameter) of about 25-100 nanometers, 25-45 nanometers, about 30-40 nanometers, or about 37 nanometers. Alternatively, or in addition, the hole conductor layer 18 may include an electrolytic salt and/or a low surface tension solvent, if desired.

### EXAMPLES

The invention may be further clarified by reference to the following examples, which serve to exemplify some illustrative embodiments, and are not meant to be limiting in any way.

### Example 1

Electron conversion efficiency was measured in four prepared samples. The results can be found in Table 1 below. Samples A and B included a 2.2 micrometer thick TiO₂ electron conductor film where the average particle diameter was about 12 nanometers. Samples C and D included a 2.4 micrometer thick TiO₂ electron conductor film where the average particle diameter was about 37 nanometers.

The results show increased efficiency in Samples C and D (e.g., which may have about 10-25% increased efficiency in solar cells like solar cell 10 that include electron conductor layers 14 that have an increased average particle diameter).

TABLE 1
Electron conversion efficiency of
4 sample electron conductor films

| Sample | V_{oc}¹ | J_{sc}² | FF³ | Efficiency | IPCE⁴ |
|---|---|---|---|---|---|
| A | 0.48 | 0.86 | 0.52 | 0.071 | 76.95 |
| B | 0.47 | 0.85 | 0.49 | 0.066 | 75.81 |
| C | 0.49 | 0.86 | 0.55 | 0.076 | 77.28 |
| D | 0.48 | 0.86 | 0.56 | 0.075 | 76.70 |

¹Open circuit voltage in V.
²Short circuit current density.
³Fill factor
⁴Incident photon to electron conversion efficiency at 455 nanometer, %

Note, the IPCE (incident photo to electron conversion efficiency) is proportional to light harvesting efficiency and electron transfer efficiency at short circuit statues (e.g., where all electrons are transferred out with no internal loss due to electron-hole recombination between the electron conductor layer). Because similar IPCE values were observed at 455 nanometers for Samples A/B and Samples C/D, these samples would appear to have similar capability to convert light into electricity in the absence of recombination. This indicates that the increased efficiency observed in Samples C and D relative to Samples A and B is not primarily due to changes in the thickness of the film, but rather it is due to reduced recombination.

### Example 2

Electron conversion efficiency was measured in eight samples. The results can be found in Table 2 below. Each sample utilized a different recipe for forming the hole conductor layer 18 as follows:

Sample A included 1 part Na₂S, 0.1 parts S, and 0.2 parts KCl dissolved in a 1:1 (by volume) mixture of methanol and deionized water.

Sample B included 1 part Na₂S, 0.1 parts S, and 0.2 parts NaF dissolved in a 1:1 (by volume) mixture of methanol and deionized water.

Sample C included 1 part Na₂S and 0.1 parts S dissolved in a 1:1 (by volume) mixture of methanol and deionized water.

Sample D included 1 part Na₂S, 0.1 parts S, 0.1 parts NaOH, and 0.2 parts KCl dissolved in deionized water.

Sample E included 1 part Na₂S, 0.1 parts S, 0.1 parts NaOH, and 0.2 parts NaF dissolved in deionized water.

Sample F included 1 part Na₂S, 0.1 parts S, and 0.1 parts NaOH dissolved in deionized water.

Sample G included 1 part Na₂S, 0.1 parts S, and 0.1 parts NaOH dissolved in deionized water.

Sample H included 1 part Na₂S and 0.1 parts S dissolved in a 1:1 (by volume) mixture of acetonitrile and water.

For all the samples, the hole conductor layer was used in combination with a TiO₂ electron conductor layer having an average particle diameter of about 37 nanometers.

The results indicated that the addition of an electrolytic salt to the hole conductor layer increased the conversion efficiency by about 5-10% (e.g., comparing samples D and E with samples F and G).

Also, the addition of a mixture of water and a low surface tension liquid (e.g., methanol) to the hole conductor layer solution increased the conversion efficiency of the resulting solar cell sample by about 20% (e.g., comparing sample C with samples F and G).

The addition of both an electrolytic salt and a mixture of water and a low surface tension liquid (e.g., methanol) to the hole conductor layer solution increased the conversion efficiency of the resulting solar cell sample by about 30-40% (e.g., comparing samples A and B with samples F and G). Thus, manufacturing hole conductor layer 18 by adding both an electrolytic salt and a mixture of water and a low surface tension liquid (e.g., methanol) may increase the conversion efficiency by about 30-40%.

TABLE 2
Electron conversion efficiency of 8 sample hole conductors

| Sample | V_{oc}¹ | J_{sc}² | FF³ | Efficiency (%) |
|---|---|---|---|---|
| A | 0..599 | 10.932 | 0.504 | 3.302 |
| B | 0.598 | 9.916 | 0.507 | 3.008 |
| C | 0.600 | 9.372 | 0.498 | 2.799 |
| D | 0.586 | 9.456 | 0.468 | 2.626 |
| E | 0.579 | 9.540 | 0.451 | 2.491 |
| F | 0.592 | 9.252 | 0.433 | 2.369 |
| G | 0.575 | 9.692 | 0.414 | 2.306 |
| H | 0.540 | 9.252 | 0.312 | 1.560 |

¹Open circuit voltage in V.
²Short circuit current density.
³Fill factor

This disclosure should not be considered limited to the particular examples described herein, but rather should be understood to cover all aspects of the invention as set out in the attached claims. Various modifications, equivalent processes, as well as numerous structures to which the invention can be applicable will be readily apparent to those of skill in the art upon review of the instant specification.

We claim:

1. A solar cell, comprising:
an electron conductor layer;
a quantum dot layer coupled to the electron conductor layer; and
a hole conductor layer coupled to the quantum dot layer, wherein the hole conductor layer includes sulfur and a low surface tension solvent.

2. The solar cell of claim 1, wherein the low surface tension solvent includes methanol.

3. The solar cell of claim 1 wherein the electron conductor layer includes ZnO.

4. The solar cell of claim 1, wherein the electron conductor layer includes TiO₂.

5. The solar cell of claim 1, wherein the electron conductor layer includes a plurality of nanoparticles having an average outer dimension that is greater than about 25 nanometers.

6. The solar cell of claim 1, wherein the plurality of nanoparticles have an average diameter of between 25-200 nanometers.

7. The solar cell of claim 1, wherein the plurality of nanoparticles have an average diameter of between 30-60 nanometers.

8. The solar cell of claim 1, wherein the plurality of nanoparticles have an average diameter of about 37 nanometers.

9. The solar cell of claim 1, wherein the hole conductor layer includes an electrolytic salt.

10. The solar cell of claim 8, wherein the electrolytic salt includes KCl.

11. The solar cell of claim 8, wherein the electrolytic salt includes NaF.

12. A solar cell, comprising:
an electron conductor layer;
a quantum dot layer coupled to the electron conductor layer; and
a hole conductor layer coupled to the quantum dot layer, wherein the hole conductor layer includes an electrolytic salt.

13. The solar cell of claim 12, wherein the electron conductor layer includes ZnO.

14. The solar cell of claim 12, wherein the electron conductor layer includes TiO₂.

15. The solar cell of claim 12, wherein the electron conductor layer includes a plurality of nanoparticles having an average outer dimension that is greater than about 25 nanometers.

16. The solar cell of claim 12, wherein the electron conductor layer includes a plurality of nanoparticles having an average diameter of between 25-200 nanometers.

17. The solar cell of claim 12, wherein the electron conductor layer includes a plurality of nanoparticles having an average diameter of between 30-60 nanometers.

18. The solar cell of claim 12, wherein the electrolytic salt includes KCl.

19. The solar cell of claim 12, wherein the electrolytic salt includes NaF.

20. A method for manufacturing a solar cell, the method comprising:
providing an electron conductor layer;
coupling a quantum dot layer to the electron conductor layer; and
coupling a hole conductor layer to the quantum dot layer, wherein the hole conductor layer includes a sulfur-based liquid hole conductor in a low surface tension solvent.

21. The method of claim 20, wherein the low surface tension solvent is a mixture that includes water and methanol.

22. The method of claim 20, wherein the hole conductor layer includes an electrolytic salt.

23. The method of claim 20, wherein the electron conductor layer includes a plurality of nanoparticles having an average diameter greater than about 25 nanometers.
